(19) United States
(12) Patent Application Publication
(10) Pub. No.: US 2007/0064393 A1
(43) Pub. Date: Mar. 22, 2007

(54) Heat dissipating system

(76) Inventors: Chien-Jung Chen, Kaohsiung Hsien (TW); Te-Tsung Chen, Kaohsiung Hsien (TW); Chih-Tsung Hsu, Kaohsiung Hsien (TW)

Correspondence Address: GALLAGHER & LATHROP, A PROFESSIONAL CORPORATION, 601 CALIFORNIA ST, SUITE 1111, SAN FRANCISCO, CA, 94108, US

(21) Appl. No.: 11/392,104

(22) Filed: Mar. 28, 2006

(30) Foreign Application Priority Data
Sep. 21, 2005 (TW) 094216233

(51) Int. Cl. H05K 7/20

(52) U.S. Cl. 361/699

(57) ABSTRACT

A heat dissipating system for cooling an electronic device includes: a heat sink adapted to be connected to the electronic device for absorbing heat from the electronic device; a cooling fluid containing a coolant and a particulate material dispersed in the coolant; a driving mechanism; a cooling mechanism; and a coolant circulating conduit. The coolant circulating conduit receives the cooling fluid therein, and is connected to the heat sink and the driving mechanism. The driving mechanism drives circulation of the cooling fluid in the coolant circulating conduit through the heat sink. The coolant circulating conduit is further coupled to the cooling mechanism so as to transfer heat from the heat sink to the cooling mechanism through the cooling fluid.

### CROSS-REFERENCE TO RELATED APPLICATION

This application claims priority of Taiwanese application no. 094216233, filed on Sep. 21, 2005.

### BACKGROUND OF THE INVENTION

1. Field of the Invention

This invention relates to a heat dissipating system, more particularly to a heat dissipating system for cooling an electronic device.

2. Description of the Related Art

As technology advances in the field of computers, performance of the computer has become more and more powerful. Therefore, considerable heat is generated by electronic devices, such as a central processing unit (CPU) of the computer, thereby resulting in a high temperature. The high temperature can cause improper shut down of the computer and damage to the data stored in the computer. Thus, heat dissipation is a major concern for computer manufacturers.

FIG. 1 shows a conventional heat dissipating device 1. The conventional heat dissipating device 1 includes a heat sink 11, a coolant 12, a driving mechanism 13, a cooling mechanism 14, and a conduit 112 allowing the coolant 12 to flow therein and connected to the heat sink 11 and the driving mechanism 13.

The heat sink 11 includes a body 111 heat-exchangably connected to an electronic device 100, and defines a space in the body 111. The coolant 12 is received in the space of the heat sink 11, and flows through the space of the heat sink 11 so as to carry the heat from the electronic device 100.

The driving mechanism 13 is used to circulate the coolant 12 in the heat dissipating system 1.

The cooling mechanism 14 includes a plurality of heat dissipating fins 142 spaced apart from each other and connected to a tortuous section 141 of the conduit 112.

In operation, the heat generated by the electronic device 100 is transferred to the body 111 of the heat sink 11, and is carried by the coolant 12 to the cooling mechanism 14. In the cooling mechanism 14, the coolant is cooled to reduce the temperature thereof. The heat dissipating fins 142 of the cooling mechanism 14 contact the tortuous section 141 of the conduit 112 so as to facilitate heat dissipation. With the circulation of the coolant 12, the heat generated by the electronic device 100 is dissipated.

As described above, because of the advance of technology, there is a need in the art to provide a heat dissipating system with superior heat-exchanging efficiency as compared to the prior art.

### SUMMARY OF THE INVENTION

Therefore, the object of the present invention is to provide a heat dissipating system for cooling an electronic device that has a higher heat dissipating efficiency as compared to the prior art.

According to this invention, a heat dissipating system for cooling an electronic device comprises: a heat sink adapted to be connected to the electronic device for absorbing heat from the electronic device; a cooling fluid containing a coolant and a particulate material dispersed in the coolant; a driving mechanism; a cooling mechanism; and a coolant circulating conduit. The coolant circulating conduit receives the cooling fluid therein, and is connected to the heat sink and the driving mechanism. The driving mechanism drives circulation of the cooling fluid in the coolant circulating conduit through the heat sink. The coolant circulating conduit is coupled to the cooling mechanism so as to transfer heat from the heat sink to the cooling mechanism through the cooling fluid.

### BRIEF DESCRIPTION OF THE DRAWINGS

Other features and advantages of the present invention will become apparent in the following detailed description of the preferred embodiment of this invention, with reference to the accompanying drawings, in which:

FIG. 1 is a schematic view of a conventional heat dissipating device; and

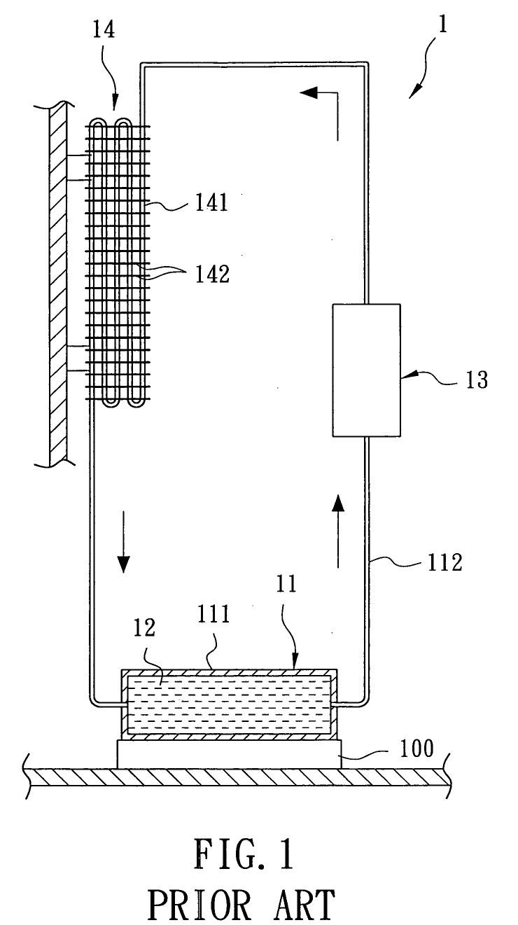

FIG. 2 is a schematic view of the preferred embodiment of a heat dissipating system according to this invention.

### DETAILED DESCRIPTION OF THE PREFERRED EMBODIMENT

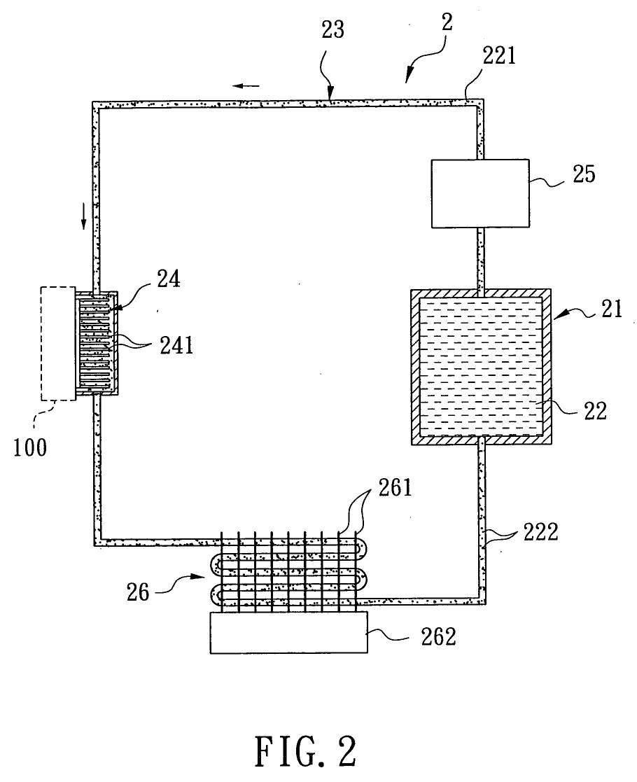

Referring to FIG. 2, the preferred embodiment of a heat dissipating system 2 according to this invention includes: a heat sink 24 adapted to be connected to an electronic device 100 for absorbing heat from the electronic device 100; a cooling fluid 22 containing a coolant 221 (water is used as the coolant 221 in this embodiment) and a particulate material 222 dispersed in the coolant 221; a pump as a driving mechanism 25; a cooling mechanism 26; and a coolant circulating conduit 23 receiving the cooling fluid 22 therein, and connected to the heat sink 24 and the pump 25 that drives circulation of the cooling fluid 22 in the coolant circulating conduit 23 through the heat sink 24. The coolant circulating conduit 23 is coupled to the cooling mechanism 26 so as to transfer heat from the heat sink 24 to the cooling mechanism 26 through the cooling fluid 22.

Preferably, the particulate material 222 has a specific heat lower than the coolant 221. Preferably, the particulate material 222 is selected from the group consisting of copper, aluminum, and the combination thereof, and has an average particle size in a nanometer range.

In this embodiment, the heat sink 24 includes a plurality of fins 241 spaced apart from each other and in contact with the cooling fluid 22. The fins 241 provide a larger surface area for heat-exchange from the electronic device 100 to the cooling fluid 22, thereby enhancing the heat dissipating efficiency.

In this embodiment, the cooling mechanism 26 includes a plurality of fins 261 and a fan 262. The fins 261 of the cooling mechanism 26 are spaced apart from each other, and contact the coolant circulating conduit 23, such that heat is transferred to the fins 261 of the cooling mechanism 26 from the cooling fluid 22 through the coolant circulating conduit 23. The fan 262 of the cooling mechanism 26 is used to cool the fins 261 of the cooling mechanism 26.

In operation, the heat generated by the electronic device 100 is transferred to the fins 241 of the heat sink 24. The cooling fluid 22 passes through the heat sink 24, and absorbs heat from the fins 241 of the heat sink 24 so as to carry the heat from the heat sink 24. The heated cooling fluid 22 is cooled when passing through the cooling mechanism 26. The cooled cooling fluid 22 is re-circulated to the heat sink 24 through the driving action of the pump 25, thereby continuing the heat-exchanging circulation.

Preferably, the heat dissipating system 2 further includes a reservoir 21 for receiving the cooling fluid 22. The reservoir 21 is made from a material with low specific heat, and is connected to the coolant circulating conduit 23. The driving mechanism 25 is disposed downstream of the reservoir 21, and draws the cooling fluid 22 from the reservoir 21 into the coolant circulating conduit 23.

In this embodiment, the electronic device 100 is directly connected to the heat sink 24. However, this invention is not limited to the disclosed embodiment. For example, the electronic device 100 can be directly connected to the reservoir 21.

According to this invention, since the cooling fluid 22 contains the particulate material 222 with lower specific heat than the coolant 221, the efficiency of heat dissipation in this invention is better than the efficiency in the case in which only the coolant is used. Therefore, a heat dissipating system with improved heat dissipating efficiency is realized in this invention.

While the present invention has been described in connection with what is considered the most practical and preferred embodiment, it is understood that this invention is not limited to the disclosed embodiment but is intended to cover various arrangements included within the spirit and scope of the broadest interpretation and equivalent arrangements.

What is claimed is:

1. A heat dissipating system for cooling an electronic device, said heat dissipating system comprising:
a heat sink adapted to be connected to the electronic device for absorbing heat from the electronic device;
a cooling fluid containing a coolant and a particulate material dispersed in said coolant;
a driving mechanism;
a cooling mechanism; and
a coolant circulating conduit receiving said cooling fluid therein, and connected to said heat sink and said driving mechanism that drives circulation of said cooling fluid in said coolant circulating conduit through said heat sink, said coolant circulating conduit being coupled to said cooling mechanism so as to transfer heat from said heat sink to said cooling mechanism through said cooling fluid.

2. The heat dissipating system of claim 1, wherein said particulate material has a specific heat lower than said coolant.

3. The heat dissipating system of claim 2, wherein said particulate material is selected from the group consisting of copper, aluminum, and the combination thereof.

4. The heat dissipating system of claim 1, wherein said particulate material has an average particle size in a nanometer range.

5. The heat dissipating system of claim 1, wherein said coolant is water.

6. The heat dissipating system of claim 1, wherein said heat sink includes a plurality of fins in contact with said cooling fluid.

7. The heat dissipating system of claim 1, wherein said cooling mechanism includes a fan and a plurality of fins spaced apart from each other and in contact with said coolant circulating conduit.

8. The heat dissipating system of claim 1, wherein said driving mechanism includes a pump.

9. The heat dissipating system of claim 1, further comprising a reservoir connected to said coolant circulating conduit for storing said cooling fluid, said driving mechanism drawing said cooling fluid from said reservoir into said coolant circulating conduit.
